(19) United States
(12) Patent Application Publication
(10) Pub. No.: US 2024/0201587 A1
(43) Pub. Date: Jun. 20, 2024

(54) ADDITIVES FOR METALLIC PHOTORESIST

(71) Applicant: Taiwan Semiconductor Manufacturing Company, Hsinchu (TW)

(72) Inventors: An-Ren Zi, Hsinchu (TW); Hui-Chun Lee, Hsinchu (TW); Peng-Ting Lee, Hsinchu (TW); Ching-Yu Chang, Yuanshan (TW)

(21) Appl. No.: 18/093,537

(22) Filed: Jan. 5, 2023

Related U.S. Application Data
(60) Provisional application No. 63/428,833, filed on Nov. 30, 2022.

(51) Int. Cl. G03F 7/004; G03F 7/32

(52) U.S. Cl. CPC G03F 7/0045; G03F 7/0043; G03F 7/32

(57) ABSTRACT

Methods and materials for reducing the radiation dosage needed for development of a metallic photoresist are disclosed. During development, the metallic photoresist is exposed to an additive that comprises (i) one aromatic group with one or more substituents having at least one saturated endgroup; or (ii) a plurality of aromatic groups linked together through a linking moiety. Improved line resolution is also obtained.

### CROSS-REFERENCE TO RELATED APPLICATIONS

This application claims priority to U.S. Provisional Patent Application Ser. No. 63/428,833, filed on Nov. 30, 2022, which is incorporated by reference in its entirety.

### BACKGROUND

Integrated circuits are formed on a semiconductor wafer. Photolithographic patterning processes use ultraviolet light to transfer a desired mask pattern to a photoresist on a semiconductor wafer. Etching processes may then be used to transfer to the pattern to a layer below the photoresist. This process is repeated multiple times with different patterns to build different layers on the wafer substrate and make a useful device.

High-resolution lithography processes are needed to obtain smaller feature sizes. An example of one such process is extreme ultraviolet (EUV) lithography, which uses wavelengths of about 10 nanometers (nm) to about 100 nm. Further improvements are desired.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a flow chart illustrating a method for preparing a patterned photoresist layer and etching a layer of a semiconducting device, in accordance with some embodiments.

FIG. 1B is a second flow chart illustrating other aspects of the method.

FIG. 2A is a cross-sectional view of a substrate prior to starting the method of FIG. 1A and FIG. 1B.

FIG. 2B is a cross-sectional view of a substrate with a first material layer located upon the substrate, again prior to starting the method of FIG. 1A and FIG. 1B.

FIG. 3 is a cross-sectional view of the substrate with two underlayers applied upon the first material layer.

FIG. 4 is a cross-sectional view of the substrate with a photoresist layer applied upon the two underlayers.

FIG. 5 is a cross-sectional view of the substrate after radiation exposure, with the photoresist layer now including soluble regions and insoluble regions.

FIG. 6 is a cross-sectional view of the substrate after development, with a patterned photoresist layer.

FIG. 7 is a cross-sectional view of the final structure with a patterned first material layer.

FIG. 8 is an illustration of an extreme ultraviolet (EUV) photolithography system for exposing the photoresist layer to EUV radiation, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number.

The term “aromatic” refers to a group that has a ring system containing a delocalized conjugated pi system with a number of pi-electrons that obeys Hückel's Rule. The ring system is composed of carbon atoms and hydrogen atoms. Examples of aromatic groups include phenyl (derived from benzene) and other polycyclic aromatic hydrogens such as naphthyl (derived from naphthalene) or phenanthryl (derived from phenanthrene). Generally, the aromatic group is planar and un-charged.

The term “alkyl” as used herein refers to a radical composed from a chain of carbon atoms which is fully saturated (i.e. contains only single bonds). The alkyl radical may be linear, branched, or cyclic.

The term “halogen” as used herein refers to fluorine, chlorine, bromine, and iodine.

The term “alkenyl” as used herein refers to a radical composed from a chain of carbon atoms which contains at least one double bond and is not aromatic. The alkenyl radical may be linear, branched, or cyclic.

The term “carboxyl” refers to a radical of the formula —CO—O—, and can also refer to the salt thereof. The carboxy radical bonds through the carbon atom and one of the oxygen atoms.

The term “amino” refers to a radical of the formula —NR¹— or —NR¹R², where R¹ and R² are independently hydrogen or alkyl. This includes monosubstituted radicals (i.e. where R² is hydrogen) and disubstituted radicals (where neither R¹ nor R² are hydrogen).

The present disclosure may refer to temperatures for certain process steps. It is noted that these generally refer to the temperature at which the heat source (e.g. furnace) is set, and do not necessarily refer to the temperature which must be attained by the material being exposed to the heat.

The term “ambient temperature” or “room temperature” refers to a temperature of 15° C. to 30° C.

The present disclosure relates to structures which are made up of different layers. When the terms “on” or “upon” are used with reference to two different layers (including the substrate), they indicate merely that one layer is on or upon the other layer. These terms do not require the two layers to directly contact each other, and permit other layers to be between the two layers. For example all layers of the structure can be considered to be “on” the substrate, even though they do not all directly contact the substrate. The term “directly” may be used to indicate two layers directly contact each other without any layers in between them. In addition, when referring to performing process steps to the substrate, this should be construed as performing such steps to whatever layers may be present on the substrate as well, depending on the context.

The present disclosure relates to various methods for improving the operation of a metallic photoresist. In this regard, chemically amplified photoresist may be considered as operating through a multi-step reaction mechanism. First, when exposed to EUV radiation, the photoresist absorbs photons from the radiation. Second, secondary electrons are emitted by the photoresist, and thermal electrons are also generated. Third, photo-acid generators (PAGs) react with these electrons to generate photoacids. Fourth, the photoacids diffuse through the photoresist matrix. Fifth and last, the photoacid catalyzes the degradation of acid-sensitive groups from the photoresist, also known as deprotection. The photoacid is not consumed in this reaction, and can thus catalyze multiple deprotection reactions. The deprotected photoresist differs from the original photoresist in solubility. This difference in the photoresist between exposed areas and non-exposed areas permits patterning of the photoresist, which is used to build different layers on the wafer substrate.

A metallic photoresist includes metal atoms to increase photon absorption, i.e. the first step of the reaction mechanism. However, the performance of the metallic photoresist can be improved.

The present disclosure relates to additives and methods for using such additives to reduce the required radiation dosage needed to develop a metallic photoresist while still obtaining good results with smaller radiation dosages. Briefly, the additive includes one or more aromatic groups along with either a saturated endgroup or a linking moiety which links multiple aromatic groups together. These aspects are discussed in more detail below. Initially, the additive is described, along with other components of a photoresist solution such as a metallic photoresist, Next, methods for using the photoresist solutions containing the additive will be described.

### Additive

During the photoresist development process, the photoresist can be exposed to an additive which aids in development while reducing the needed radiation dosage. Without being bound by theory, the additive generates additional radicals upon activation, which increases radical transfer and increases cross-linking in the photoresist. Unlike other components of the photoresist, the additive does not contain metal. The additive may have two different structures.

First, the additive may generally have one aromatic group which has one or more substituents with a saturated endgroup. In these embodiments, the additive may have the structure of Formula (1):

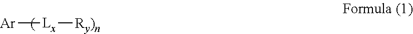

wherein Ar is an aromatic group;
wherein each L is independently saturated C₁-C₉ alkyl, —S—, —P—, —P(O)₂—, —COS—, —COO—, —O—, —NH—, —CON—, —SO₂O—, —SO₂S—, —SO—, or -SO2 ;
wherein each x is independently 0 to 6;
wherein each R is independently saturated C₁-C₁₂ alkyl;
wherein each y is 1 to 6; and
wherein n is 1 up to the number of substitutable carbon atoms in Ar.

With respect to aromatic groups Ar, Ar¹, and Ar², the hydrogen atoms of the aromatic groups may be substituted with halogen atoms or other substituents as described above.

The substituent —Lₓ—R_{y} of Formula (1) includes one or more linking groups L and one or more saturated endgroups R. When more than one linking group L is present, the linking groups can be arranged linearly or in a branched manner. As a non-limiting example of branched linking groups, L could be a combination of three linking groups such as a 1,2-diaminoethyl chain —CH(NH—)—CH(NH—)—. Similarly, in some embodiments, the number of saturated endgroups may differ from the number of linking groups in a given substituent, or in other words x≠y. In the event of any ambiguity, the formula —Lₓ—R_{y}, the atoms of a given substituent should be interpreted as being part of a saturated endgroup R instead of a linking group L. For example, if the substituent is of the formula —C₉H₁₉, the substituent should be considered as being made up of one saturated endgroup R which is a C₉ alkyl, and should not be construed as being made up of, for example one linking group L which is C₈ alkyl and one saturated endgroup R which is a C₁ alkyl. In some particular embodiments, each linking group L is independently saturated C₁-C₉ alkyl, —O—, or —NH—.

With respect to the saturated endgroup(s) R, it is contemplated that each carbon atom in the endgroup is saturated with hydrogen or halogen atoms. In particular embodiments, each carbon atom is saturated with only hydrogen or fluorine atoms, or with only hydrogen atoms.

In some particular embodiments of Formula (1), x=0, or in other words no linking groups are present at all. In some additional embodiments of Formula (1), x=1. In other particular embodiments, n is 1 or 2.

The total number of —Lₓ—R_{y} substituents n on the aromatic group Ar is at least 1, and may vary depending on the total number of substitutable carbon atoms in the aromatic group Ar. For example, if Ar is phenyl, n may be from 1 to 6, and if Ar is naphthyl, n may be from 1 to 8. In some particular embodiments of Formula (1), n is from 1 to 6 regardless of the number of substitutable carbon atoms.

Some more specific embodiments of Formula (1) are shown below as Formulas (1-a) through (1-d):

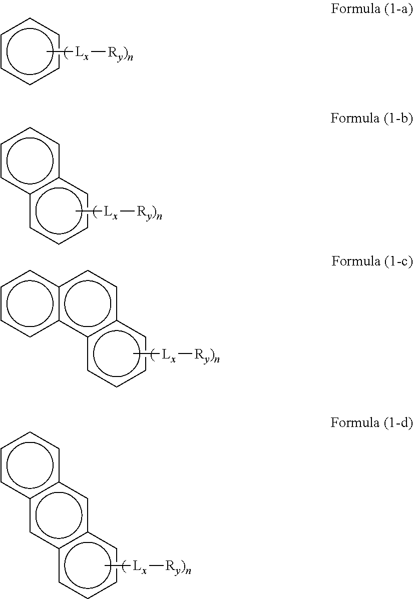

where L, x, R, y, and n are as defined above with respect to Formula (1).

Some specific non-limiting examples of compounds falling within the scope of Formula (1) and Formula (1-a) include toluene; o-xylene, m-xylene, and p-xylene; propylbenzene; 2-ethyltoluene; 4-isopropyltoluene; 1,3-diethylbenzene; isopropylbenzene; 1,2-diethylbenzene; and 4-tert-butyltoluene.

Second, the additive may have a plurality of aromatic groups which are linked together through a linking moiety. In these embodiments, the additive may have the structure of Formula (2):

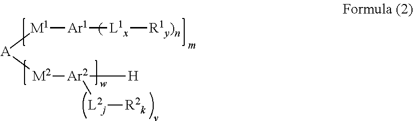

wherein A is C₁-C₉ alkyl, —S—, —P—, —P(O)₂—, —COS—, —COO—, —O—, —NH—, —CON—, —SO₂O—, —SO₂S—, —SO—, or —SO₂—;
wherein each M¹ and M² is independently a covalent bond, saturated C₁-C₉ alkyl, —S—, —P—, —P(O)₂—, —COS—, —COO—, —O—, —NH—, —CON—, —SO₂O—, —SO₂S—, —SO—, or —SO₂—;
wherein each Ar¹ and Ar² are independently an aromatic group;
wherein each L¹ and L² is independently saturated C₁-C₉ alkyl, —S—, —P—, —P(O)₂—, —COS—, —COO—, —O—, —NH—, —CON—, —SO₂O—, —SO₂S—, —SO—, or —SO₂—;
wherein each x and j is independently 0 to 6;
wherein each R¹ and R² is independently saturated C₁-C₁₂ alkyl;
wherein each y and k is independently 1 to 6;
wherein each n is 0 up to the number of substitutable carbon atoms in Ar¹;
wherein each v is 0 up to the number of substitutable carbon atoms in Ar²; and
wherein m and w are independently 0 to 10, and m+w is at least 2.

The discussion of aromatic group Ar of Formula (1) also applies to the aromatic groups Ar¹ and Ar² of Formula (2). The discussion of the substituent —Lₓ—R_{y} of Formula (1) also applies to the substituents and —L¹ₓ—R¹_{y} and —L²ⱼ—R²ₖ of Formula (2).

In particular embodiments of Formula (2), x and j are both zero, i.e. no linking groups L¹ or L² are present in the substituents. In other particular embodiments of Formula (2), x and j are both 1. In other particular embodiments of Formula (2), n and v are both zero, i.e. there are no substituents with saturated endgroups. As mentioned above, m+w is at least 2, and in some particular embodiments is from 2 to 4.

In the additive of Formula (2), the linking moiety A links at least two aromatic groups Ar¹ and Ar² together. In particular embodiments, the linking moiety A is a linear C₁-C₉ alkyl, —O—, —NH—, —COO—, or —CON—.

In some particular embodiments, the spacers M¹ and M² are covalent bonds and do not represent an atom. It is noted that the variable w is usually not 1, but either zero or 2 to 10. It is noted that multiple —M²—Ar²— groups represent multiple aromatic groups Ar² which are linked directly together or with a spacer M² between adjacent aromatic groups.

Some more specific embodiments of Formula (2) are shown below as Formula (2-a) through (2-b):

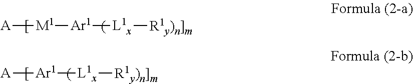

wherein A, M¹, Ar¹, L¹, x, R¹, y, n, and m are as defined above with respect to Formula (2). These may be considered variants of Formula (2) where w=0 and/or where M¹ is a covalent bond.

Twelve specific non-limiting examples of compounds falling within the scope of Formula (2), Formula (2-a), and Formula (2-b) are shown below:

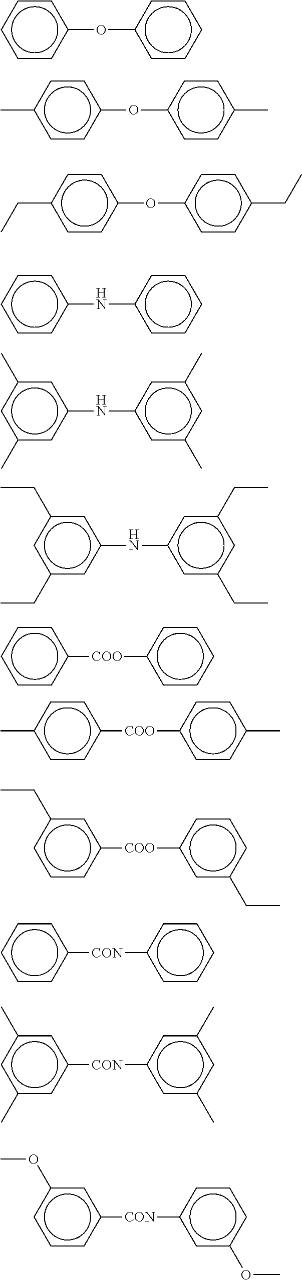

In these 12 examples, referring back to Formula (2), w=0 and m=2, and M¹ is a covalent bond. In 11 of these examples x=0. The bottommost example in the righthand column is 3-methoxy-N-(3-methoxyphenyl)benzamide, and here x=1. In the eight examples of the middle and righthand columns, n=2.

Another example of a compound falling within the scope of Formula (2) is shown below:

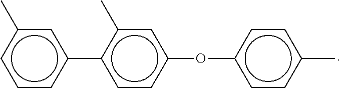

In this example, A=—O—; m=1; M¹ is a covalent bond; x=0; y=1; w=2, and for each Ar² group M2 is a covalent bond, j=0, and k=1.

The additive of Formula (1) or Formula (2) may have a molecular weight of about 78 to about 780. In particular embodiments, the additive of Formula (1) has a molecular weight of about 78 to less than 220, or from about 90 to about 150. In other particular embodiments, the additive of Formula (2) has a molecular weight of about 78 to about 290.

The additive is typically provided in a liquid form, for example as a treatment solution in which the additive is dissolved. The solvent may be, for example, propylene glycol methyl ether acetate (PGMEA), propylene glycol monomethyl ether (PGME), 1-ethoxy-2-propanol (PGEE), gamma-butyrolactone (GBL), cyclohexanone (CHN), ethyl lactate (EL), methanol, ethanol, propanol, n-butanol, acetone, dimethylformamide (DMF), isopropyl alcohol (IPA), tetrahydrofuran (THF), methyl isobutyl carbinol (MIBC), n-butyl acetate (nBA), or 2-heptanone (MAK). In some embodiments, the additive may be dissolved to a final concentration of about 500 ppm to about 500,000 ppm (i.e. about 0.05 wt % to about 50 wt %).

In other embodiments, if the additive is liquid at the operating temperature, the concentration of the additive may be 100 wt %. For example, toluene, xylene, isopropylbenzene, diphenyl ether, 1-methylnaphthalene, 2-methylnaphthalene, and 1-methylphenanthrene all have melting points below 150° C., which is within the operating temperatures of some steps in the photoresist development process. Put another way, no solvent is needed if the additive is liquid, and the treatment solution may comprise only the additive itself. Thus, the additive may be present in the treatment solution in an amount of about 0.01 wt % to about 100 wt %.

A treatment solution containing these additives may be heated prior to their use to obtain a liquid, for example up to a temperature of about 200° C. The additive is used in an amount of about 0.01 wt % to about 50 wt % relative to the metallic photoresist.

All combinations of any two or more of these different ranges and values for the different variables (A, M¹, Ar¹, L¹, x, R¹, y, n, and m, M², Ar², L², j, R², k, v, and w, molecular weight, and concentration) are contemplated as being within the scope of the present disclosure.

As will be described in further detail herein, the photoresist development process includes the steps of coating the substrate, a prebake or softbake, radiation exposure, an optional post-exposure bake, development, and an optional hardbake. The additives of the present disclosure can be used during any of these process steps, or could be used between any of the process steps. The additive may be provided in a liquid phase or a gas/vapor phase, depending on the operating temperature and pressure of the particular process step.

### Photoresist Solution

A photoresist solution is generally used to prepare a photoresist layer on a semiconducting wafer substrate. The photoresist solution includes a metallic photoresist, and may also include a cross-linker and a solvent.

The metallic photoresist generally comprises a metal core and one or more ligands attached to or connected to the metal core. The ligand(s) may be attached via covalent, ionic, or metallic bonds or via van der Waals forces to the metal core.

The metal core of the metallic photoresist includes a metallic element. The metallic element may be present as a pure metal (i.e. atom), an ion, a compound (for example a metal oxide, metal nitride, metal oxynitride, metal silicide, metal carbide, etc.), or as an alloy of multiple metal atoms. Desirably, the metallic element has a high EUV photoabsorption. Examples of suitable metallic elements include silver (Ag), cadmium (Cd), indium (In), tin (Sn), antimony (Sb), tellurium (Te), cesium (Cs), gold (Au), mercury (Hg), titanium (Ti), lead (Pb), bismuth (Bi), polonium (Po), astatine (At), barium (Ba), lanthanum (La), cerium (Ce), hafnium (Hf), zirconium (Zr), chromium (Cr), tungsten (W), molybdenum (Mo), iron (Fe), ruthenium (Ru), osmium (Os), cobalt (Co), rhodium (Rh), iridium (Ir), nickel (Ni), palladium (Pd), platinum (Pt), copper (Cu), zinc (Zn), aluminum (Al), gallium (Ga), thallium (TI), and germanium (Ge). In more specific embodiments, the metal core of the metallic photoresist comprises Ag, Cd, In, Sn, Sb, Te, Cs, Au, Hg, Ti, Pb, Bi, Po, At, Ba, La, or Ce. The metallic elements in the metal core of the metallic photoresist may comprise from about 0.01 wt % to about 7 wt % of the photoresist solution. In some particular embodiments, only one metallic element is present in the metal core. In other embodiments, multiple metallic elements are present in the metal core.

The ligand(s) are attached to the metal core, and this attachment determines whether the photoresist is soluble or insoluble when exposed to developer. One function of the ligand(s) is to protect the metal core from condensation prior to radiation exposure. The ligands are cleaved from the metal core during radiation exposure. In particular embodiments, there are from 1 to about 18 ligands attached to the metal core. Each ligand may include from 1 to 12 carbon atoms, which may be linear, branched, or cyclic, and which may be alkyl or alkenyl groups, or may be aromatic. Other functional groups may also be present in the ligand, such as carboxyl or amino groups.

The cross-linker may also contain a metal core, or may be a conventional cross-linker.

In particular embodiments, the solvent used in the photoresist solution may be PGMEA, PGME, PGEE, GBL, cyclohexanone, ethyl lactate, methanol, ethanol, propanol, n-butanol, acetone, DMF, isopropyl alcohol (IPA), THF, MIBC, n-butyl acetate, or MAK.

If desired, the photoresist solution may also include a photoacid generator (PAG), a photobase generator (PBG), a thermal acid generator (TAG), a quencher, and/or an adhesion promoter.

### Process

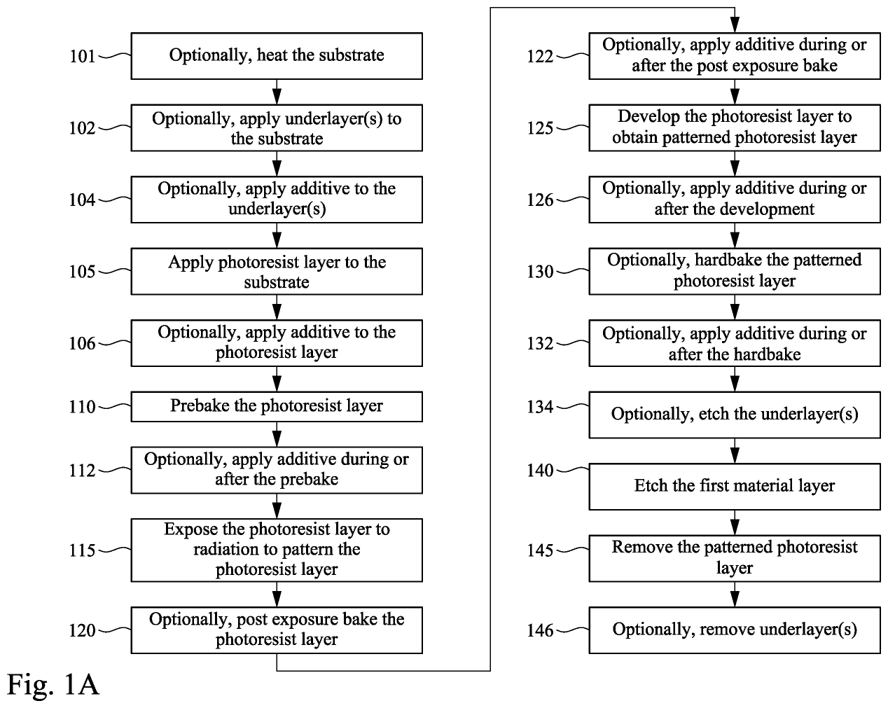

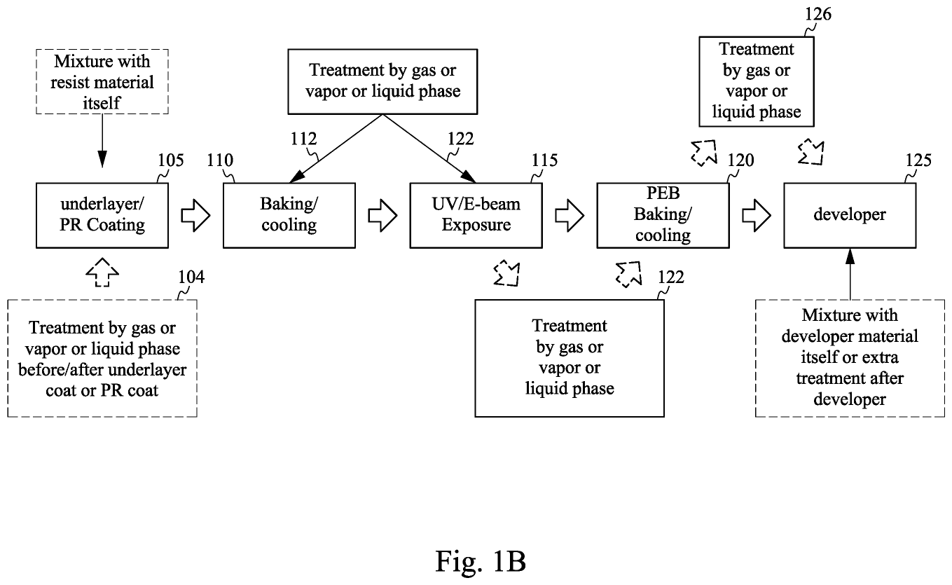

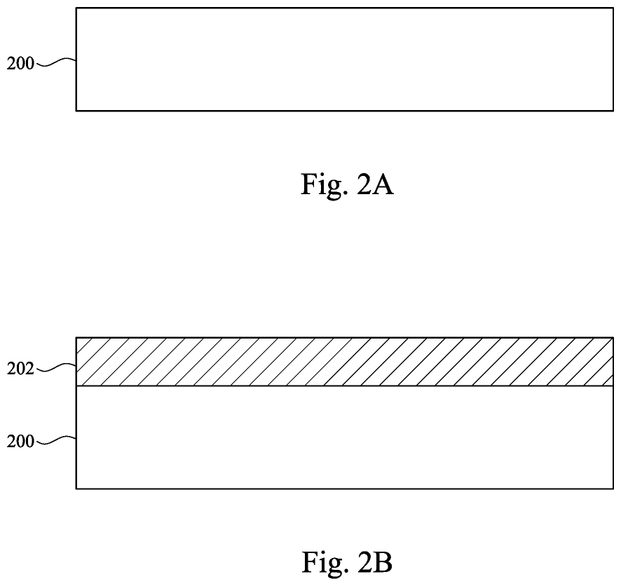

FIG. 1A is a flow chart illustrating a method 100 for preparing a patterned photoresist layer and etching a layer of a semiconducting device, in accordance with some embodiments. FIG. 1B is another flow chart illustrating other aspects of the method. In the discussion below, FIG. 1A will generally be referred to. Some steps of the method are also illustrated in FIGS. 2A-7. These figures provide different views for better understanding.

Referring first to FIG. 2A, this figure shows one example of the beginning state of the substrate 200 prior to any processing steps. The substrate is usually a wafer made of a semiconducting material. Such materials can include silicon, for example in the form of crystalline Si or polycrystalline Si. In alternative embodiments, the substrate can be made of other elementary semiconductors such as germanium, or may include a compound semiconductor such as silicon carbide (SiC), gallium arsenide (GaAs), gallium carbide, gallium phosphide, indium arsenide (InAs), indium phosphide (InP), silicon germanium, silicon germanium carbide, gallium arsenic phosphide, or gallium indium phosphide. In particular embodiments, the wafer substrate is silicon. As illustrated here, no additional layers are present upon the substrate 200.

In contrast, in FIG. 2A, a first material layer 202 is present upon the substrate 200. The first material layer may be any material that may be used in a semiconducting device or integrated circuit. For example, the first material layer could be made of an insulating material, such as silicon dioxide (SiO2) or silicon nitride (SiN), silicon oxynitride (SiON), fluoride-doped silicate glass, or other dielectric material. As another example, the first material layer could be made of an electrically conductive material, such as polysilicon or a metal like aluminum, copper, titanium, or tungsten. The discussion below proceeds with a first material layer being present, for illustrative purposes only and with it being understood that the substrate can also be etched.

It may be desirable to heat the substrate prior to beginning the photoresist patterning process. This optional heating step 101 may improve resist adhesion by desorbing water present on the substrate surface and to thermally crack any hydroxide bonds present on an oxidized surface. The substrate can be heated to temperatures above 100° C. up to, for example, 200° C. for a period of several minutes. The substrate is then cooled back down to room temperature.

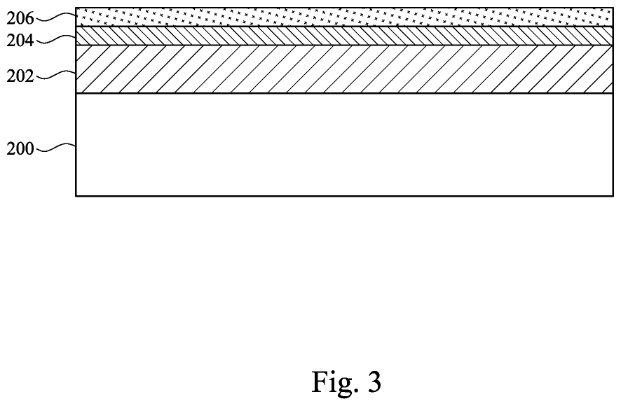

Referring again to FIG. 1A, in optional step 102, one or more underlayers are applied to the substrate. In this regard, the term “underlayer” is relative to the photoresist layer, and refers to any layers which may be applied to the layer that is desired to be etched prior to applying the photoresist layer. Put another way, any layers between the layer to be etched and the photoresist layer can be considered an underlayer. In one non-limiting example illustrated in FIG. 3, two underlayers 204, 206 are applied upon the first material layer 202.

As one example, the lower underlayer 204 may be a bottom anti-reflective coating (BARC). When a photoresist layer is applied to a reflective substrate, light reflection from the substrate/resist interface can create variations in light exposure, that cause problems with critical dimension (CD) control. For example, light can reflect into areas where exposure was not intended, changing the desired pattern. A BARC can be applied between the substrate and the photoresist layer to minimize or eliminate such problems. Examples of suitable BARCs include amorphous carbon and various organic polymers. The BARC layer is typically formed by spin coating, though other methods can also be used. The BARC coating or film is then baked or cured to induce crosslinking and solvent removal, and hardening of the BARC. In some particular embodiments, the baking occurs at a temperature of about 125° C. to about 275° C. In particular embodiments, the baking takes place for a time of about 30 seconds to about 250 seconds. The baking can be performed using a hot plate or similar equipment.

As another example, the upper underlayer 206 may be a hard mask layer. The hard mask layer may be formed from a dielectric material, a metal, or other suitable material. Examples of suitable dielectric materials may include silicon carbide, silicon nitride, silicon oxycarbide, or silicon oxynitride. The hard mask layer may be formed by any suitable process such as chemical vapor deposition (CVD), low-pressure CVD (LPCVD), plasma-enhanced CVD (PECVD), physical vapor deposition (PVD), atomic layer deposition (ALD), or spin coating. The BARC layer and the hard mask layer are also typically selected to have significantly different etching sensitivity towards the same etchant. Combined with the photoresist layer, this multi-layer resist pattern can also help improve line width roughness (LWR).

When underlayers are used, as indicated in optional step 104 of FIG. 1A, the additive can be mixed in with the materials for the underlayer or applied to either underlayer. This can be done by applying the additive in the liquid phase (e.g. the treatment solution) or in the gas phase, for example by vaporizing the treatment solution during the baking/curing of the underlayer.

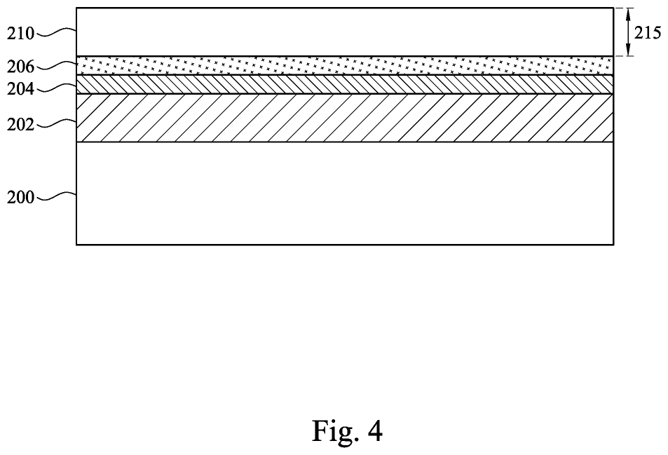

Next, in step 105 of FIG. 1A and as illustrated in FIG. 4, a photoresist (PR) layer 210 is applied over the substrate. The photoresist layer is formed by applying the photoresist solution containing the metallic photoresist. If desired, the additive can be added directly into the photoresist solution. The photoresist solution may be applied, for example, by spin coating, or by spraying, roller coating, dip coating, or extrusion coating. Typically, in spin coating, the substrate is placed on a rotating platen, which may include a vacuum chuck that holds the substrate in plate. The photoresist solution is then applied to the center of the substrate. The speed of the rotating platen is then increased to spread the resist evenly from the center of the substrate to the perimeter of the substrate. The rotating speed of the platen is then fixed, which can control the thickness of the final photoresist layer. FIG. 4 shows the resulting structure after this step.

If desired, the additive can be mixed directly into the photoresist solution. Alternatively, as indicated in optional step 106 of FIG. 1A, the additive can be applied after the photoresist layer has been applied. Again, the additive could be applied in the liquid phase, for example by spraying or misting the treatment solution upon the photoresist layer.

Next, in step 110 of FIG. 1A, the photoresist solution is prebaked to remove the solvent and harden the photoresist layer. This may also be referred to as a softbake. In some particular embodiments, the prebake occurs at a temperature of about 40° C. to about 100° C., including from about 250° C. to about 800° C. or from about 90° C. to about 110° C. The time for the prebake may depend upon the thickness of the photoresist layer 210, with longer times for greater thicknesses, and in particular embodiments from about 10 seconds to about 10 minutes. Referring to FIG. 4, the photoresist layer 210 may have a thickness 215 of about 10 nanometers to about 100 nanometers. The baking can be performed using a hot plate or oven, or similar equipment. As a result, the photoresist layer is formed on the substrate. The substrate and the other layers thereon are then cooled down to room temperature.

As indicated in optional step 112 of FIG. 1A, the additive can be applied during or after the prebake. The additive could be applied as a liquid, or can be vaporized by the heating that occurs in the prebake step and be applied as a gas.

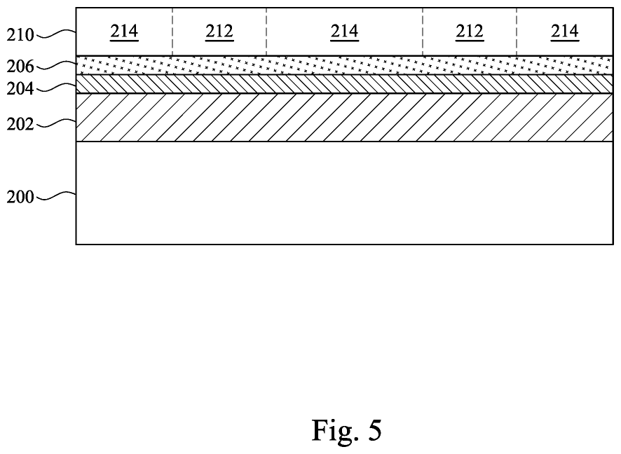

Continuing, in step 115 of FIG. 1A, the photoresist layer 210 is then patterned via exposure to radiation. The radiation may be any light wavelength which carries a desired mask pattern. In particular embodiments, EUV light having a wavelength of about 13.5 nm is used for patterning, as this permits smaller feature sizes to be obtained. In other embodiments, electron-beam (e-beam) radiation is used. Electron beams can be characterized by the energy of the beam, which in some embodiments ranges from about 5 kilovolts (kV) to about 200 kV. This step results in some portions of the photoresist layer being exposed to radiation, and some portions of the photoresist not being exposed to radiation. This exposure causes some portions of the photoresist to remain soluble in the developer and other portions of the photoresist to become insoluble in the developer. Referring now to FIG. 5, the photoresist layer 210 now includes soluble regions 212 and insoluble regions 214. It is noted for reference that EUV and e-beam radiation exposure typically occur under vacuum.

Optionally, in step 120 of FIG. 1A, a post exposure bake (PEB) occurs after the exposure to radiation. The PEB step can be used to complete any cross-linking within the photoresist, or to complete any chemically amplified reactions that may occur (for example if only the metallic cross-linker is used with the CAR). In addition, the PEB step may reduce mechanical stress that might build up during the prior steps. In some particular embodiments, the PEB occurs at a temperature of about 40° C. to about 250° C., including from about 100° C. to about 250° C. or from about 90° C. to about 150° C. The time for the PEB may range from about 10 seconds to about 10 minutes, and may vary depending on the thickness of the photoresist layer.

As indicated in optional step 122 of FIG. 1A, the additive can be applied during or after the post exposure bake. The additive could be applied as a liquid or vaporized to enter the gas phase during the heating that occurs in the PEB step.

Next, in step 125 of FIG. 1A, the photoresist layer 210 is developed using a developer. The developer may be applied by spin coating, spraying, or other suitable process. The soluble portions of the photoresist layer are dissolved and washed away during the development step, leaving behind a patterned photoresist layer. This may be done, for example, by spin drying. Suitable developers may include PGMEA, PGME, PGEE, GBL, cyclohexanone, ethyl lactate, methanol, ethanol, propanol, n-butanol, acetone, DMF, isopropyl alcohol (IPA), THF, MIBC, n-butyl acetate, or MAK, i.e. the same solvent used in the photoresist solution. Other developers could include aqueous tetramethylammonium hydroxide (TMAH), isoamyl acetate, cyclohexanone, 5-methyl-2-hexanone, methyl-2-hydroxyisobutyrate, n-pentyl acetate, n-butyl propionate, n-hexyl acetate, n-butyl butyrate, isobutyl butyrate, 2,5-dimethyl-4-hexanone, 2,6-dimethyl-4-heptanone, propyl isobutyrate, or isobutyl propionate. Generally, any suitable developer may be used.

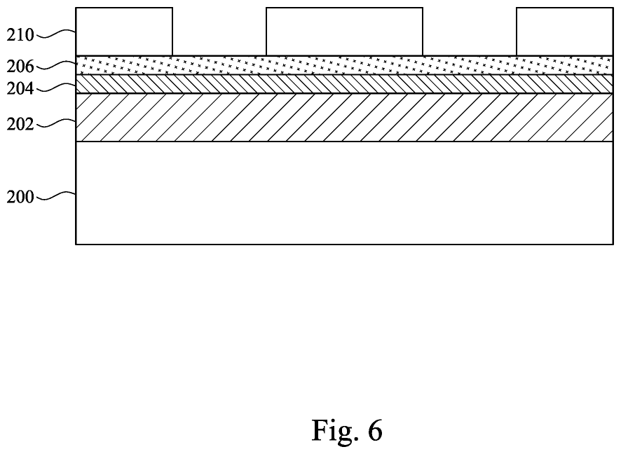

If desired, the additive can be mixed directly into the developer. Alternatively, as indicated in optional step 126 of FIG. 1A, the additive can be applied after the developer has been applied and then washed off the substrate. Again, the additive could be applied in the liquid phase, for example by spraying or misting the treatment solution. The resulting structure is illustrated in FIG. 6. As seen here, the soluble regions have been washed away, resulting in a patterned photoresist layer.

In optional step 130 of FIG. 1A, a post develop bake or “hardbake” may be performed after development. This can be done to stabilize the photoresist pattern after development, for optimum performance in subsequent steps. In some particular embodiments, the hardbake occurs at a temperature of about 100° C. to about 160° C. The time for the hardbake may range from about 1 minute to about 10 minutes, and may vary depending on the thickness of the photoresist layer.

As indicated in optional step 132 of FIG. 1A, the additive can be applied during or after the hardbake. The additive could be applied as a liquid (i.e. treatment solution) or vaporized to enter the gas phase during the heating that occurs in the hardbake step.

Continuing, then, portions of the upper underlayer 206, the lower underlayer 204, and the first material layer 202 below the patterned photoresist layer are now exposed.

In optional step 134 of FIG. 1A, the underlayer(s) 206, 204 are etched, thus transferring the photoresist pattern to the underlayers. Then, in step 140 of FIG. 1A, the first material layer 202 is etched through the patterned photoresist layer, thus transferring the photoresist pattern to the first material layer and obtain a patterned material layer. Desirably, each of the etchants for these layers differs significantly from that of the other layers, which improves the LWR in the first material layer. It should be understood that the patterned material layer can be either the first material layer or the substrate as well. In some embodiments, the first material layer is an insulating layer, and the etched pattern may subsequently be filled with a conductive material to form a circuit within this insulating layer. In other alternate embodiments, the first material layer is a conductive layer, and the etched pattern is subsequently filled with an insulating material.

Generally, these etching steps may be performed using wet etching, dry etching, or plasma etching processes such as reactive ion etching (RIE) or inductively coupled plasma (ICP), or combinations thereof, as appropriate. The etching may be anisotropic. Depending on the material, etchants may include carbon tetrafluoride (CF₄), hexafluoroethane (C₂F₆), octafluoropropane (C₃F₈), fluoroform (CHF₃), difluoromethane (CH₂F₂), fluoromethane (CH₃F), trifluoromethane (CHF₃), carbon fluorides, nitrogen (N₂), hydrogen (H₂), oxygen (O₂), argon (Ar), xenon (Xe), xenon difluoride (XeF₂), helium (He), carbon monoxide (CO), carbon dioxide (CO₂), fluorine (F₂), chlorine (Cl₂), oxygen (O₂), hydrogen bromide (HBr), hydrofluoric acid (HF), nitrogen trifluoride (NF₃), sulfur hexafluoride (SF₆), boron trichloride (BCl₃), ammonia (NH₃), bromine (Br₂), nitrogen trifluoride (NF₃), or the like, or combinations thereof in various ratios. For example, silicon dioxide can be wet etched using hydrofluoric acid and ammonium fluoride. Alternatively, silicon dioxide can be dry etched using various mixtures of CHF₃, O₂, CF₄, and/or H₂.

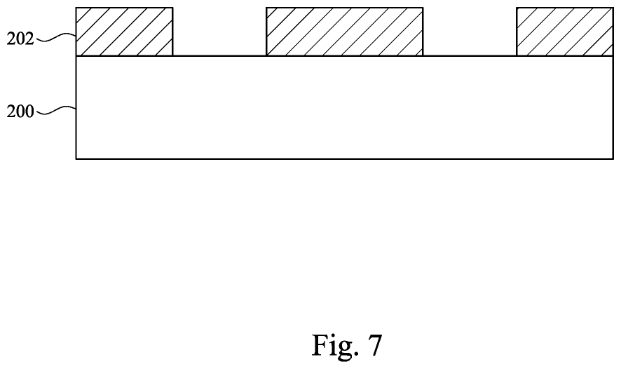

Next, in step 145 of FIG. 1A, the patterned photoresist layer 210 is removed. In optional step 146, the upper underlayer 206 is removed. In optional step 148, the lower underlayer 204 is removed. The photoresist layer, the upper underlayer, and the lower underlayer can be removed using conventional means such as plasma stripping, solvent, or chemical-mechanical planarization (CMP). The resulting structure is illustrated in FIG. 7, with the first material layer 202 being patterned.

Referring now to FIG. 1B, the two different treatment options are shown more clearly here. In the photoresist coating step 105 and the developing step 125, the additive can be directly mixed into the photoresist solution or the development solution. This is indicated in dotted lines. Alternatively, the additive can be used in the form of a treatment solution which is applied to the photoresist. More desirably, the additive is used before, during, or after a step in which energy is added to the photoresist. Those include the radiation exposure step 115, the pre-bake step 110, and the post exposure bake step 120, in which light energy or thermal energy are added. This is indicated with solid lines.

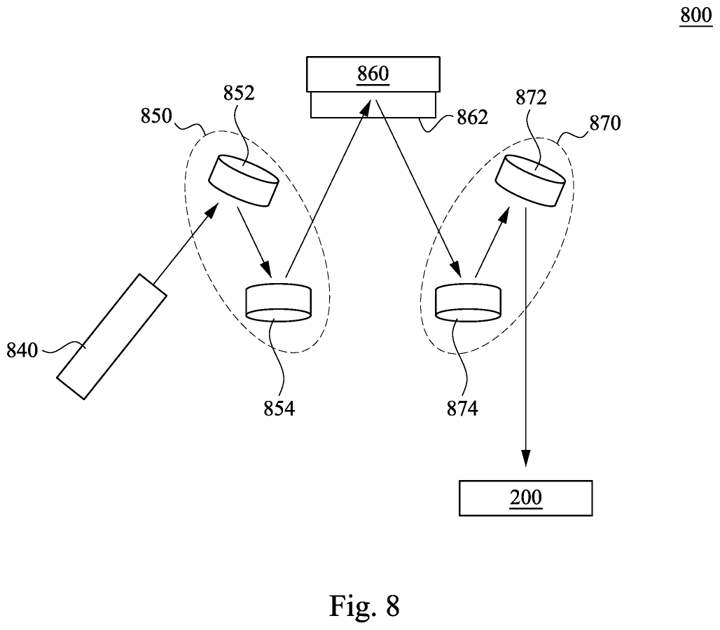

FIG. 8 is an illustrative schematic diagram, not drawn to scale, illustrating the various components of an extreme ultraviolet (EUV) photolithography system which generates the radiation to which the photoresist is exposed. Generally, the EUV photolithography system 800 begins with an EUV light source 840 that generates EUV light or radiation. Downstream of the EUV light source is an illumination stage 850 in which the EUV light may be collected and focused as a beam, for example using field facet mirror 852 that splits the beam into a plurality of light channels. These light channels can then directed using one or more relay mirrors 854 onto the plane of the photomask. The photomask 860 may include a pellicle membrane 862, through which the radiation passes before and/or after contacting the photomask. Downstream of the photomask 860 is the projection optics module 870, which is configured for imaging the pattern of the photomask onto the semiconductor wafer substrate 200. The projection optics module 870 may include refractive optics or reflective optics for carrying the image of the pattern defined by the photomask. Illustrative mirrors 872, 874 are shown. The lithography system can include other modules or be integrated with or coupled to other modules.

Additional processing steps may be performed to fabricate a semiconductor device or integrated circuit. Examples of such steps may include ion implantation, deposition of other materials, etching, etc.

Use of the additive comprising (i) one aromatic group with one or more substituents having at least one saturated endgroup; or (ii) a plurality of aromatic groups linked together through a linking moiety provides some advantages. The radiation dosage can be reduced by 5% or more while still obtaining patterns with high resolution and good LWR. The LWR can be less than 5.0 nanometers, and the radiation dosage can be less than 70 mJ/cm². The performance of the metallic photoresist at optimum energy (Eₒₚ) can be improved by more than 3%, and the number of defects can be reduced by more than 5%. Processes with a pitch of 40 nanometers or lower (line edge to line edge) can be improved using the additive along with the photoresist.

Some embodiments of the present disclosure thus relate to methods that use a photoresist solution. The substrate is coated with a photoresist solution. The coated substrate is pre-baked to cure the photoresist solution and form a photoresist layer. The photoresist layer is then exposed to radiation to pattern the photoresist layer. An optional post-exposure bake of the coated substrate may be performed. The patterned photoresist layer is then developed using a developer. The photoresist solution or the developer may include an additive that comprises (i) one aromatic group with one or more substituents having at least one saturated endgroup; or (ii) a plurality of aromatic groups linked together through a linking moiety. Alternatively, the coated substrate is treated with a treatment solution that the additive during or after the coating, pre-baking, exposing, optional post-exposure bake, or developing steps.

Other embodiments of the present disclosure relate to methods for improving photoresist performance. A photoresist layer is formed on a substrate. The photoresist layer comprises a metallic photoresist. The photoresist layer is treated with a treatment solution containing an additive. The additive comprises (i) one aromatic group with one or more substituents having at least one saturated endgroup; or (ii) a plurality of aromatic groups linked together through a linking moiety.

Finally, other embodiments of the present disclosure relate to a photoresist solution. The photoresist solution comprises a metallic photoresist; and an additive that comprises (i) one aromatic group with one or more substituents having at least one saturated endgroup; or (ii) a plurality of aromatic groups linked together through a linking moiety.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
coating a substrate with a photoresist solution comprising a metallic photoresist;
pre-baking the coated substrate to cure the photoresist solution and form a photoresist layer;
exposing the photoresist layer to radiation to pattern the photoresist layer;
optionally performing a post-exposure bake of the coated substrate;
developing the patterned photoresist layer using a developer;
optionally hardbaking the patterned photoresist layer; and
etching through the patterned photoresist layer to obtain a patterned material layer;
wherein either (A) the photoresist solution or the developer includes an additive or (B) the coated substrate is treated with a treatment solution that contains the additive during or after the coating, pre-baking, exposing, optional post-exposure bake, or developing steps;
wherein the additive comprises (i) one aromatic group with one or more substituents having at least one saturated endgroup; or (ii) a plurality of aromatic groups linked together through a linking moiety.

2. The method of claim 1, wherein the additive has the structure of Formula (1): 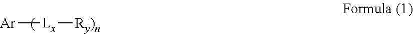
wherein Ar is an aromatic group;
wherein each L is independently saturated C₁-C₉ alkyl, —S—, —P—, —P(O)₂—, —COS—, —COO—, —O—, —NH—, —CON—, —SO₂O—, —SO₂S—, —SO—, or —SO₂—;
wherein each x is independently 0 to 6;
wherein each R is independently saturated C₁-C₁₂ alkyl;
wherein each y is 1 to 6; and
wherein n is 1 up to the number of substitutable carbon atoms in Ar.

3. The method of claim 2, wherein Ar is phenyl, napthyl, or phenanthrenyl.

4. The method of claim 2, wherein each x is zero; or wherein n is 1 or 2.

5. The method of claim 2, wherein each R is saturated with hydrogen or halogen.

6. The method of claim 2, wherein the additive has a molecular weight of less than 220.

7. The method of claim 2, wherein the additive comprises toluene, xylene, propylbenzene, 2-ethyltoluene, 4-isopropyltoluene, 1,3-diethylbenzene, isopropylbenzene, 1,2-diethylbenzene, or 4-tert-butyltoluene.

8. The method of claim 1, wherein the additive has the structure of Formula Formula (2): 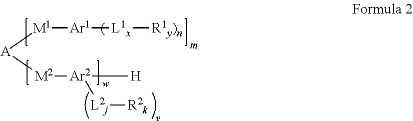
wherein A is C₁-C₉ alkyl, —S—, —P—, —P(O)₂—, —COS—, —COO—, —O—, —NH—, —CON—, —SO₂O—, —SO₂S—, —SO—, or —SO₂—;
wherein each M¹ and M² is independently a covalent bond, saturated C₁-C₉ alkyl, —S—, —P—, —P(O)₂—, —COS—, —COO—, —O—, —NH—, —CON—, —SO₂O—, —SO₂S—, —SO—, or —SO₂—;
wherein each Ar¹ and Ar² are independently an aromatic group;
wherein each L¹ and L² is independently saturated C₁-C₉ alkyl, —S—, —P—, —P(O)₂—, —COS—, —COO—, —O—, —NH—, —CON—, —SO₂O—, —SO₂S—, —SO—, or —SO₂—;
wherein each x and j is independently 0 to 6;
wherein each R¹ and R² is independently saturated C₁-C₁₂ alkyl;
wherein each y and k is independently 1 to 6;
wherein each n is 0 up to the number of substitutable carbon atoms in Ar¹;
wherein each v is 0 up to the number of substitutable carbon atoms in Ar²; and
wherein m and w are independently 0 to 10, and m+w is at least 2.

9. The method of claim 8, wherein the additive has one of the following chemical structures:

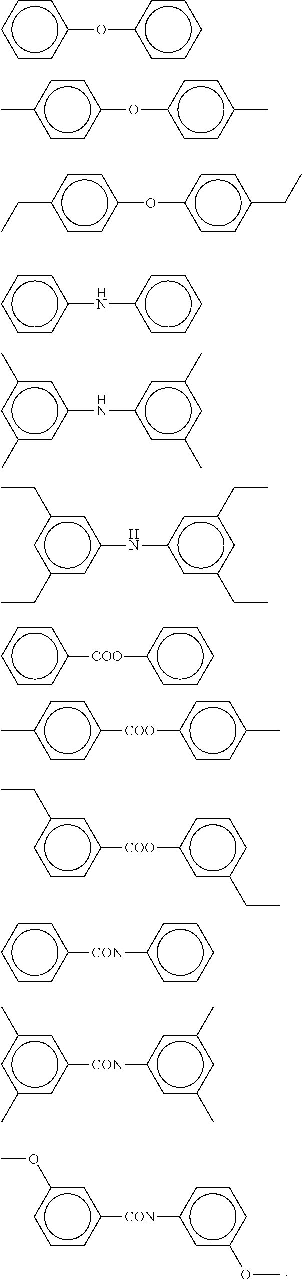

10. The method of claim 8, wherein each M¹ and M² is a covalent bond; each x and j is zero; and m+w=2.

11. The method of claim 8, wherein the additive has a molecular weight of about 78 to about 290.

12. The method of claim 1, wherein the additive has a molecular weight of about 78 to about 780.

13. The method of claim 1, wherein the treatment with the treatment solution containing the additive is performed by vaporizing the treatment solution containing the additive.

14. The method of claim 1, wherein the treatment solution further comprises a solvent comprising propylene glycol methyl ether acetate (PGMEA), propylene glycol monomethyl ether (PGME), 1-ethoxy-2-propanol (PGEE), gamma-butyrolactone (GBL), cyclohexanone (CHN), ethyl lactate (EL), methanol, ethanol, propanol, n-butanol, acetone, dimethylformamide (DMF), isopropyl alcohol (IPA), tetrahydrofuran (THF), methyl isobutyl carbinol (MIBC), n-butyl acetate (nBA), or 2-heptanone (MAK).

15. The method of claim 1, wherein the additive is present in the treatment solution in an amount of about 0.01 wt % to 100 wt %.

16. The method of claim 1, wherein the additive is used in an amount of about 0.01 wt % to about 50 wt % relative to the metallic photoresist.

17. A method for improving photoresist performance, comprising:
forming a photoresist layer comprising a metallic photoresist on a substrate;
treating the photoresist layer with a treatment solution containing an additive;
wherein the additive comprises (i) one aromatic group with one or more substituents having at least one saturated endgroup; or (ii) a plurality of aromatic groups linked together through a linking moiety.

18. The method of claim 17, wherein the saturated endgroup is C₁-C₁₂ alkyl, or wherein the linking moiety is C₁-C₉ alkyl, —COO—, —O—, —NH—, or —CON—.

19. A photoresist solution, comprising:
a metallic photoresist; and
an additive that comprises (i) one aromatic group with one or more substituents having at least one saturated endgroup; or (ii) a plurality of aromatic groups linked together through a linking moiety.

20. The method of claim 19, wherein the metallic photoresist comprises Ag, Cd, In, Sn, Sb, Te, Cs, Au, Hg, Ti, Pb, Bi, Po, At, Ba, La, or Ce.
